(19) United States
(12) Patent Application Publication
(10) Pub. No.: US 2018/0057710 A1
(43) Pub. Date: Mar. 1, 2018

(54) POLISHING COMPOSITION AND POLISHING METHOD

(71) Applicant: FUJIMI INCORPORATED, Kiyosu-shi (JP)

(72) Inventor: AKIHITO YASUI, Kiyosu-shi (JP)

(21) Appl. No.: 15/551,867

(22) PCT Filed: Feb. 8, 2016
(86) PCT No.: PCT/JP2016/000647

§ 371 Date: Aug. 17, 2017

(30) Foreign Application Priority Data
Feb. 24, 2015 (JP) 2015-033938

(51) Int. Cl. C09G 1/02; H01L 21/304

(52) U.S. Cl. CPC C09G 1/02; H01L 21/304

(57) ABSTRACT

To provide a polishing composition which is hard to cause etching or corrosion in a polishing target containing a transition metal having a standard electrode potential of -0.45 V or more and 0.33 V or less even when used for polishing the polishing target. The polishing composition contains abrasives and a metal protecting organic compound. The metal protecting organic compound has an interactive functional group which is a functional group interacting with a polishing target containing a transition metal having a standard electrode potential of −0.45 V or more and 0.33 V or less and an inhibiting functional group which is a functional group inhibiting the approach of the abrasives toward the polishing target.

### TECHNICAL FIELD

The present invention relates to a polishing composition and a polishing method.

### BACKGROUND ART

An anticorrosive or a surfactant is added to a polishing composition for use in metal polishing in order to inhibit etching or corrosion of metals caused by the polishing composition (Patent Document 1). However, the anticorrosive or the surfactant has sometimes promoted etching or corrosion depending on the metal type. In particular, a transition metal having a standard electrode potential of −0.45 V or more and 0.33 V or less has a property that the resistance to water, acids, agents, such as a complexing agent and an oxidizer, is low, and therefore etching or corrosion have tended to be easily promoted.

### CITATION LIST

### Patent Literature

PTL 1: JP 2009-81300 A

### SUMMARY OF INVENTION

### Technical Problem

Then, it is an object of the present invention to solve the problems of former techniques described above, and then provide a polishing composition which is hard to cause etching or corrosion in a polishing target containing a transition metal having a standard electrode potential of −0.45 V or more and 0.33 V or less even when used for polishing of the polishing target and a polishing method.

### Solution to Problem

In order to solve the problems described above, a polishing composition according to one aspect of the present invention is a polishing composition polishing a polishing target containing a transition metal having a standard electrode potential of −0.45 V or more and 0.33 V or less, and the polishing composition contains abrasives and a metal protecting organic compound, in which the metal protecting organic compound has an interactive functional group which is a functional group interacting with the polishing target and an inhibiting functional group which is a functional group inhibiting the approach of the abrasives toward the polishing target.

A polishing method according to another aspect of the present invention includes polishing a polishing target using the polishing composition according to the one aspect described above.

### Advantageous Effects of Invention

According to the polishing composition and the polishing method of the present invention, etching or corrosion is hard to occur in a polishing target containing a transition metal having a standard electrode potential of −0.45 V or more and 0.33 V or less.

### DESCRIPTION OF EMBODIMENT

One embodiment of the present invention is described in detail. A polishing composition of this embodiment is a polishing composition polishing a polishing target containing a transition metal having a standard electrode potential of −0.45 V or more and 0.33 V or less, and the polishing composition contains abrasives and a metal protecting organic compound. The metal protecting organic compound has an interactive functional group which is a functional group interacting with the polishing target and an inhibiting functional group which is a functional group inhibiting the approach of the abrasives toward the polishing target.

When the polishing target containing a transition metal having a standard electrode potential of −0.45 V or more and 0.33 V or less is polished using the polishing composition of this embodiment, etching or corrosion is hard to occur in the polishing target. The reason therefor is described in detail below.

An anticorrosive or a surfactant is added to a polishing composition for use in metal polishing in order to inhibit etching or corrosion of metals due to the polishing composition. For example, to a former polishing composition for use in copper polishing, benzotriazole forming a salt with copper is sometimes added as the anticorrosive. Since a copper salt film of the benzotriazole is formed on the surface of the copper, etching or corrosion of the copper is inhibited.

However, in the case of the transition metal having a standard electrode potential of −0.45 V or more and 0.33 V or less, a nitrogen atom in a nitrogen containing anticorrosive, such as benzotriazole, acts as a ligand of a complex, and therefore the nitrogen containing anticorrosive and the transition metal react with each other, so that a brittle compound or a water-soluble complex is likely to be generated. Thus, a common nitrogen containing anticorrosive tends to promote etching or corrosion of the transition metal, and therefore the common nitrogen containing anticorrosive has not been able to be added to a polishing composition for use in polishing of the transition metal having a standard electrode potential of −0.45 V or more and 0.33 V or less in some cases.

It is considered that a surfactant forms a protective film from the charges and the chemical structure thereof utilizing electrostatic adsorption, a hydrophilic-hydrophobic interaction, or a hydrophobic-hydrophobic interaction with a polishing target.

However, in the case of an anionic surfactant, when the acid dissociation constant pKa of a functional group of the surfactant is low, the action as the acid of the functional group is excessively strong. Therefore, the anionic surfactant reacts with a transition metal having a standard electrode potential of −0.45 V or more and 0.33 V or less to promote the generation of a brittle compound or a water-soluble compound. On the other hand, when the acid dissociation constant pKa of the functional group of the surfactant is high, the functional group reacts with a hydrogen ion in the polishing composition, so that the activity of the functional group is lost, and therefore an interaction (chemical adsorption) with the surface of the transition metal becomes difficult. In the case of a cationic surfactant, an interaction (chemical adsorption) with a transition metal having a standard electrode potential of −0.45 V or more and 0.33 V or less is hard to occur due to electric repulsion.

The polishing composition of this embodiment contains a metal protecting organic compound having an interactive functional group which is a functional group interacting with a polishing target and an inhibiting functional group which is a functional group inhibiting the approach of abrasives toward a polishing target, and therefore a film of the metal protecting organic compound is formed on the surface of the polishing target as a protective film due to the action of the interactive functional group and the inhibiting functional group. In detail, due to the interaction of the interactive functional group and the polishing target, the interactive functional group is chemically adsorbed to the surface of the polishing target without corroding the surface of the polishing target and the metal protecting organic compound is arranged on the surface of the polishing target to form a film (molecular arrangement film) due to the hydrophobicity of the inhibiting functional group. Thus, the surface of the polishing target is modified, and therefore etching or corrosion (for example, surface roughness) is hard to occur.

Hereinafter, the polishing composition of this embodiment is described in more detail. Various operations and measurements of physical properties described below are performed under the conditions of room temperature (20° C. or more and 25° C. or less) and relative humidity of 40% or more 50% or less unless otherwise particularly specified.

1. Polishing Target

A polishing target applicable to polishing by the polishing composition of this embodiment contains a transition metal having a standard electrode potential of −0.45 V or more and 0.33 V or less. Examples of the transition metal having a standard electrode potential of −0.45 V or more and 0.33 V or less include iron (Fe), nickel (Ni), cobalt (Co), and tungsten (W), for example. The polishing target may be one formed of at least one kind of these transition metals or may be one containing at least one kind of these transition metals.

2. Abrasives

The type of the abrasives contained in the polishing composition of this embodiment is not particularly limited and, for example, abrasives containing silica are usable. The type of the silica is not particularly limited and, for example, colloidal silica, fumed silica, sol-gel method silica, and the like are mentioned. The silica may be used singly or in combination of two or more kinds thereof. Among the above, colloidal silica and fumed silica are preferable.

The colloidal silica can be produced by the following known methods. For example, mentioned are a method by hydrolysis of alkoxysilane on p.p. 154 to 156 of “Sol-Gel Hou no Kagaku” (“Science of Sol-Gel Method”) authored by Sumio SAKKA (published by Agne Shofusha); a method including dripping methyl silicate or a mixture of methyl silicate and methanol into a mixed solvent containing water, methanol, and ammonia or ammonia and ammonium salt to cause methyl silicate and water to react with each other described in JP 11-60232 A; a method including hydrolyzing alkylsilicate with an acid catalyst, and then adding an alkali catalyst, followed by heating, to promote polymerization of silicic acid to grow particles described in JP 2001-48520 A; a method including using a specific type of hydrolysis catalyst in a specific quantity in hydrolysis of alkoxysilane described in JP 2007-153732 A, and the like. Moreover, a method for producing colloidal silica by ion-exchanging sodium silicate is also mentioned.

Examples of a method for producing fumed silica include a method employing a gas phase reaction of evaporating silicon tetrachloride, and then burning the same in an oxyhydrogen flame. Furthermore, fumed silica can be formed into a water dispersion liquid by known methods. Examples of methods for forming fumed silica into a water dispersion liquid include methods described in JP 2004-43298 A, JP 2003-176123 A, and JP 2002-309239 A, for example.

Furthermore, colloidal silica on the surface of which organic acid is fixed is usable as the colloidal silica. Examples of the organic acid include sulfonic acid, carboxylic acid, sulfinic acid, and phosphonic acid.

When sulfonic acid is fixed to the colloidal silica, the fixation can be performed by a method described in “Sulfonic acid-functionalized silica through quantitative oxidation of thiol groups”, Chem. Commun. 246-247 (2003), for example. Specifically, a silane coupling agent having a thiol group, such as 3-mercaptopropyl trimethoxy silane, is caused to react with a hydroxy group on the surface of the colloidal silica for coupling, and then the thiol group is oxidized with hydrogen peroxide, whereby the colloidal silica on the surface of which sulfonic acid is fixed can be obtained.

The average primary particle diameter of the abrasives contained in the polishing composition of this embodiment may be 5 nm or more and preferably 10 nm or more and more preferably 15 nm or more. When the average primary particle diameter of the abrasives is within the ranges mentioned above, the polishing rate of a polishing target is improved. On the other hand, the average primary particle diameter of the abrasives contained in the polishing composition of this embodiment may be 400 nm or less and preferably 300 nm or less, more preferably 200 nm or less, and still more preferably 100 nm or less. When the average primary particle diameter of the abrasives is within the ranges mentioned above, a surface having few defects and low surface roughness can be easily obtained by polishing.

When the remaining of abrasives having a large particle diameter on the surface of a polishing target after polishing poses a problem, it is preferable to polish the polishing target with a polishing composition containing abrasives having a small particle diameter (The average primary particle diameter is 200 μm or less, for example.) not including a large particle diameter.

The average primary particle diameter of the abrasives can be calculated from the specific surface area measured by a nitrogen adsorption method (BET method), for example.

The content of the abrasives in the polishing composition may be 0.005 mass % or more and preferably 0.01 mass % or more, more preferably 0.05 mass % or more, and still more preferably 0.1 mass % or more. When the content of the abrasives is within the ranges mentioned above, the polishing rate of the polishing target by the polishing composition is improved.

On the other hand, the content of the abrasives in the polishing composition may be 50 mass % or less and preferably 30 mass % or less and more preferably 20 mass % or less. When the content of the abrasives is within the ranges mentioned above, the production cost of the polishing composition decreases. Moreover, the amount of the abrasives remaining on the surface of the polishing target after polishing decreases and the cleaning properties of the surface of the polishing target are improved.

3. Metal Protecting Organic Compound

The metal protecting organic compound contained in the polishing composition of this embodiment has an interactive functional group which is a functional group interacting with a polishing target and an inhibiting functional group which is a functional group inhibiting the approach of water, an oxidizer, an oxidized metal dissolving agent, abrasives, and the like, which are polishing components contained in the polishing composition, toward the polishing target.

The acid dissociation constant pKa of the interactive functional group is preferably 1 or more and 6 or less. When the acid dissociation constant pKa of the interactive functional group is within the ranges mentioned above, the metal protecting organic compound can be chemically adsorbed to the surface of the polishing target by the interaction between the interactive functional group and the polishing target without causing etching or corrosion on the surface of the polishing target.

The type of the interactive functional group is not particularly limited. For example, a phosphoric acid group (H₂PO₄—), a carboxy group (—COOH), a sulfonic acid group, a benzenesulfonic acid group, a sorbitan group, a polypropylene glycol group, a glycerol group, a propylene glycol group, a triazole group, a betaine group, and a quaternary ammonium group are mentioned. Among the above, the interactive functional group is preferably at least one of the phosphoric acid group (H₂PO₄—) and the carboxy group (—COOH).

The phosphoric acid group, the carboxy group, the sulfonic acid group, and the benzenesulfonic acid group may be salts, such as an amine salt and a metal salt. For example, a sodium salt (—COONa), a potassium salt (—COOK), and the like may be acceptable insofar as they are carboxy groups.

As the type of the interaction occurring between the interactive functional group and the polishing target, at least one chemical bond of an ionic bond, a covalent bond, and a hydrogen bond is preferable.

The type of the inhibiting functional group is not particularly limited and aryl groups (including a condensed ring), such as a phenyl group, alkyl groups, such as a lauryl group, a hexylheptyl group, a dodecyl group, and a stearyl group, alkenyl groups, such as an oleyl group and an allyl group, and a polyoxyethylene group represented by a chemical formula —(OCH₂CH₂)ₙ— are mentioned. The alkyl group also includes a long-chain alkyl group of a polymer skeleton. Among the above, an alkyl group having 1 or more and 20 or less carbon atoms and a polyoxyethylene group in which n in the chemical formula is an integer of 1 or more and 10 or less are preferable.

The metal protecting organic compound having a long-chain alkyl group and a polyoxyethylene group having the chain length within the ranges mentioned above is likely to self-arrange on the surface of the polishing target by a hydrophobic interaction, and therefore a firm protective film can be formed on the surface of the polishing target. When the chain length of the polyoxyethylene group which is a hydrophilic group is lengthened, the hydrophobicity of the protective film decreases, so that the function as the protective film decreases. Therefore, n in the chemical formula illustrating the chain length of the polyoxyethylene group is preferably set to an integer of 10 or less.

Specific examples of the metal protecting organic compound having the interactive functional group and the inhibiting functional group described above include lauric acid, lauryl phosphate, laureth-2 phosphate, pareth-3 phosphate, pareth-6 phosphate, pareth-9 phosphate, and the like. The lauric acid, lauryl phosphate, laureth-2 phosphate, pareth-3 phosphate, pareth-6 phosphate, and pareth-9 phosphate may be not only acids but salts, such as metal salts (for example, sodium salt).

The laureth-2 phosphate is monoester of phosphoric acid and laureth-2 and the laureth-2 is polyethylene glycol ether of lauryl alcohol. The pareth-3 phosphate is an ester of phosphoric acid and pareth-3 and the pareth-3 is polyethylene glycol ether of aliphatic alcohol obtained by adding ethylene oxide to aliphatic alcohol having 12 or more and 15 or less carbon atoms. The average addition number of moles thereof is 3. The pareth-6 phosphate is an ester of phosphoric acid and pareth-6 and the pareth-6 is polyethylene glycol ether of aliphatic alcohol obtained by adding ethylene oxide to aliphatic alcohol having 12 or more and 15 or less carbon atoms. The average addition number of moles thereof is 6. The pareth-9 phosphate is an ester of phosphoric acid and pareth-9 and the pareth-9 is polyethylene glycol ether of aliphatic alcohol obtained by adding ethylene oxide to aliphatic alcohol having 12 or more and 16 or less carbon atoms. The average addition number of moles thereof is 9.

4. Additives

Various additives, such as a pH adjuster, an oxidized metal dissolving agent, an oxidizer, and a water-soluble polymer (A copolymer may be acceptable. Moreover, salts or derivatives thereof may be acceptable.), an anticorrosive, a dispersion aid, an antiseptic, and an antifungal agent may be added to the polishing composition of this embodiment, as necessary in order to increase the performance.

4-1 PH Adjuster

The pH value of the polishing composition of this embodiment can be adjusted by the addition of a pH adjuster. The polishing rate of the polishing target, the dispersibility of the abrasives, and the like can be controlled by the adjustment of the pH of the polishing composition. The pH adjuster to be used as necessary in order to adjust the pH value of the polishing composition to a desired value may be any one of acids and alkalis or may be a salt thereof. The addition amount of the pH adjuster is not particularly limited and may be adjusted as appropriate so that the polishing composition has a desired pH.

Specific examples of the acids as the pH adjuster include inorganic acids and organic acids, such as monocarboxylic acid and organic sulfuric acid. Specific examples of the inorganic acids include hydrochloric acid, sulfuric acid, nitric acid, fluoric acid, boric acid, carbonic acid, hypophosphorous acid, phosphorous acid, phosphoric acid, and the like. Specific examples of the monocarboxylic acid include formic acid, acetic acid, propionic acid, butyric acid, valeric acid, 2-methylbutyric acid, n-hexanoic acid, 3,3-dimethylbutyric acid, 2-ethylbutyric acid, 4-methylpentanoic acid, n-heptanoic acid, 2-methylhexanoic acid, n-octanoic acid, 2-ethylhexanoic acid, benzoic acid, glycolic acid, salicylic acid, glyceric acid, gluconic acid, lactic acid, diglycolic acid, 2-furancarboxylic acid, 2,5-flandicarboxylic acid, 3-furancarboxylic acid, 2-tetrahydrofuran carboxylic acid, methoxy acetic acid, methoxy phenylacetic acid, phenoxyacetic acid, and the like.

Furthermore, specific examples of the organic sulfuric acid include methanesulfonic acid, ethane sulfonic acid, isethionic acid, and the like. These acids may be used singly or in combination of two or more kinds thereof.

Among the above, sulfuric acid, nitric acid, phosphoric acid, and the like are preferable as the inorganic acids from the viewpoint of an improvement of polishing rate and glycolic acid, gluconic acid, and the like are preferable as the organic acids.

Specific examples of the base as the pH adjuster include organic bases, such as a quaternary ammonium hydroxide compound, hydroxides of alkali metals, such as potassium hydroxide, hydroxides of alkaline-earth metals, and the like. Among the above, potassium hydroxide and the quaternary ammonium hydroxide compound are preferable in terms of ease of availability. These bases may be used singly or in combination of two or more kinds thereof.

Specific examples of the alkali metals include potassium, sodium, and the like. Specific examples of the alkaline-earth metals include calcium, strontium, and the like. Specific examples of the salts include carbonate, hydrogencarbonate, sulfate, acetate, and the like. Specific examples of the quaternary ammonium include tetramethylammonium, tetraethylammonium, tetrabutylammonium, and the like.

Examples of the quaternary ammonium hydroxide compound include quaternary ammonium hydroxide or a salt thereof. Specific examples thereof include tetramethylammonium hydroxide, tetraethylammonium hydroxide, tetrabutyl ammonium hydroxide, and the like.

In place of the acids mentioned above or in combination with the acids mentioned above, salts, such as ammonium salts and alkali metal salts of acids, may be used as the pH adjuster. In particular, when a salt of a weak acid and a strong base, a salt of a strong acid and a weak base, or a salt of a weak acid and a weak base is used, the pH buffering action can be expected. Further, when a salt of strong acid and a strong base is used, the adjustment of not only the pH but the electric conductivity can be achieved by small amount addition thereof.

4-2 Oxidized Metal Dissolving Agent

In the polishing composition of this embodiment, an oxidized metal dissolving agent may be added in order to promote the dissolution of a polishing target. Examples of the oxidized metal dissolving agent include, for example, polyvalent carboxylic acids, such as oxalic acid, malonic acid, succinic acid, glutaric acid, adipic acid, pimelic acid, maleic acid, phthalic acid, malic acid, itaconic acid, citric acid, tartaric acid, ethylenediaminetetraacetic acid, nitrilotriacetic acid, hydroxyethyl ethylene diamine triacetic acid, triethylene tetramine hexaacetic acid, and diethylenetriamine pentaacetic acid.

Furthermore, examples of the oxidized metal dissolving agent include, for example, organic phosphonic acids, such as 2-aminoethylphosphonic acid, 1-hydroxyethylidene-1,1-diphosphonic acid, aminotri(methylenephosphonic acid), ethylene diamine tetrakis(methylenephosphonic acid), diethylenetriamine penta(methylenephosphonic acid), ethane-1,1-diphosphonic acid, ethane-1,1,2-triphosphonic acid, methane hydroxy phosphonic acid, and 1-phosphonobutane-2,3,4-tricarboxylic acid.

Furthermore, examples of the oxidized metal dissolving agent include ketones, such as 1,3-diketone, a phenol derivative, and ammonia, for example.

Furthermore, examples of the oxidized metal dissolving agent include, for example, amines, such as methylamine, dimethylamine, trimethylamine, ethylamine, diethylamine, triethylamine, ethylenediamine, monoethanolamine, N-(β-aminoethyl)ethanolamine, hexamethylenediamine, diethylenetriamine, triethylenetetramine, anhydrous piperazine, piperazine hexahydrate, 1-(2-aminoethyl)piperazine, N-methylpiperazine, and guanidine.

Furthermore, examples of the oxidized metal dissolving agent include, for example, amino acids, such as glycine, α-alanine, β-alanine, N-methylglycine, N,N-dimethylglycine, 2-aminobutyric acid, norvaline, valine, leucine, norleucine, isoleucine, phenylalanine, proline, sarcosine, ornithine, lysine, taurine, serine, threonine, homoserine, tyrosine, bicin, tricine, 3,5-diiodotyrosine, β-(3,4-dihydroxyphenyl)alanine, thyroxine, 4-hydroxyproline, cystein, methionine, ethionine, lanthionine, cystathionine, cystine, cysteic acid, aspartic acid, glutamic acid, S-(carboxymethyl)cystein, 4-aminobutyric acid, asparagine, glutamine, azaserine, arginine, canavanine, citrulline, δ-hydroxylysine, creatine, histidine, 1-methylhistidine, 3-methylhistidine, and tryptophan.

These oxidized metal dissolving agents may be used singly or in combination of two or more kinds thereof.

4-3 Oxidizer

An oxidizer may be added to the polishing composition of this embodiment in order to oxidize the surface of a polishing target. Specific examples of the oxidizer include hydrogen peroxide, peracetic acid, percarbonate, urea peroxide, perchlorate, persulfate, nitric acid, and the like. Specific examples of the persulfate include sodium persulfate, potassium persulfate, ammonium persulfate, and the like. The oxidizers may be used singly or in combination of two or more kinds thereof.

4-4 Water-Soluble Polymer

A water-soluble polymer (A copolymer may be acceptable. Moreover, salts or derivatives thereof may be acceptable.) acting on the surface of a polishing target or the surface of abrasives maybe added to the polishing composition of this embodiment. Specific examples of the water-soluble polymer, the water-soluble copolymer, and salts or derivatives thereof include polycarboxylic acids, such as a polyacrylic acid salt, polysulfonic acids, such as polyphosphonic acid and polystyrene sulfonic acid, polysaccharides, such as xanthan gum and sodium alginate, cellulose derivatives, such as hydroxyethylcellulose and carboxymethylcellulose, polyethylene glycol, polyvinyl alcohol, polyvinyl pyrrolidone, sorbitan monooleate, oxyalkylene-based polymers having one kind or two or more kinds of oxyalkylene units, and the like. The substances may be used singly or in combination of two or more kinds thereof.

4-5 Anticorrosive

An anticorrosive may be added to the polishing composition of this embodiment in order to inhibit the corrosion of the surface of a polishing target. Specific examples of the anticorrosive include amines, pyridines, a tetraphenyl phosphonium salt, benzotriazoles, triazoles, tetrazoles, benzoic acid, and the like. The anticorrosives may be used singly or in combination of two or more kinds thereof.

4-6 Dispersion Aid

A dispersion aid may be added to the polishing composition of this embodiment in order to facilitate the redispersion of an aggregate of abrasives. Specific examples of the dispersion aid include condensed phosphates, such as pyrophosphate and hexametaphosphate, and the like. The dispersion aids may be used singly or in combination of two or more kinds thereof.

4-7 Antiseptic

To the polishing composition of this embodiment, an antiseptic maybe added. Specific examples of the antiseptic include sodium hypochlorite and the like. The antiseptics may be used singly or in combination of two or more kinds thereof.

4-8 Antifungal Agent

To the polishing composition of this embodiment, an antifungal agent may be added. Specific examples of the antifungal agent include isothiazoline-based antiseptics, such as 2-methyl-4-isothiazoline-3-one and 5-chloro-2-methyl-4-isothiazoline-3-one, oxazolines, such as oxazolidine-2,5-dione, and the like. Moreover, para-hydroxybenzoate, phenoxyethanol, and the like are mentioned.

5. Liquid Medium

The polishing composition of this embodiment may contain a liquid medium, such as water and an organic solvent. The liquid medium functions as a dispersion medium or a solvent for dispersing or dissolving the components (the abrasives, the metal protecting organic compound, the additives, and the like) of the polishing composition. As the liquid medium, water and an organic solvent are mentioned. The liquid media can be used singly or in combination of two or more kinds thereof and preferably contain water. However, it is preferable to use water not containing impurities as much as possible from the viewpoint of inhibiting the action of each component. Specifically, pure water or ultrapure water from which impurities are removed through a filter after removing impurity ions with an ion-exchange resin or distilled water is preferable.

6. Method for Producing Polishing Composition

A method for producing the polishing composition of this embodiment is not particularly limited. The polishing composition can be produced by stirring and mixing abrasives, a metal protecting organic compound, and, as desired, various additives, in a liquid medium, such as water, for example. For example, the polishing composition can be produced by stirring and mixing abrasives containing silica, sodium laurate as the metal protecting organic compound, and various additives, such as a pH adjuster, in water. The temperature in the mixing is not particularly limited and is preferably 10° C. or more and 40° C. or less and heating may be performed in order to increase the solution rate. The mixing time is also not particularly limited.

7. Polishing Method

The polishing of a polishing target using the polishing composition of this embodiment can be performed using a polishing device and under polishing conditions for use in usual polishing. For example, a single-sided polishing device and a double-sided polishing device are usable.

For example, when a substrate formed of a transition metal is used as the polishing target and polishing is performed using a single-sided polishing device, the substrate is held using a holding fixture referred to as a carrier, a platen to which a polishing cloth is stuck is pressed against one side of the substrate, and then the platen is rotated while feeding the polishing composition, whereby the one side of the substrate is polished.

When a substrate formed of a transition metal is polished using a double-sided polishing device, the substrate is held using a holding fixture referred to as a carrier, a platen to which a polishing cloth is stuck is pressed against each of both sides of the substrate, and then the platens on the both sides are rotated while feeding the polishing composition, whereby the both sides of the substrate are polished.

In any case where either one of the polishing devices is used, the substrate is polished by a physical action due to friction (friction of the polishing cloth and the polishing composition with the transition metal) and a chemical action imparted to the transition metal by the polishing composition.

As the polishing cloth, those containing various materials, such as polyurethane, nonwoven fabric, and suede, are usable. Those which are variously different in physical properties, such as hardness and thickness, besides the difference in raw materials, are usable. Furthermore, those containing abrasives and those containing no abrasives are all usable but those containing no abrasives are preferably used.

Furthermore, a polishing load (pressure loaded to a polishing target) among the polishing conditions is not particularly limited and may be 0.7 kPa or more and 69 kPa or less. When the polishing load is within the ranges mentioned above, a sufficient polishing rate is demonstrated, so that the breakage of the polishing target due to the load, or the generation of defects, such as cracks, in the surface of the polishing target can be inhibited.

The polishing rate (linear velocity) among the polishing conditions is not particularly limited and may be 10 m/min or more and 300 m/min or less and preferably 30 m/min or more and 200 m/min or less. When the polishing rate (linear velocity) is within the ranges mentioned above, a sufficient polishing rate can be obtained. The breakage of the polishing cloth due to the friction of the polishing target can be inhibited and further the friction is sufficiently transmitted to the polishing target and a so-called state where the polishing target slides can be inhibited, so that the polishing target can be sufficiently polished.

Furthermore, the feed amount of the polishing composition among the polishing conditions also varies depending on the type of the polishing target, the type of the polishing device, and the polishing conditions and may be an amount in which the polishing composition is uniformly fed to the entire surface between the polishing target and the polishing cloth. When the feed amount of the polishing composition is small, the polishing composition is not fed to the entire polishing target or the polishing composition is dried and solidified to cause defects in the surface of the polishing target in some cases. Conversely, when the feed amount of the polishing composition is large, there is a possibility that friction is sometimes hindered due to the excess polishing composition (particularly the liquid medium, such as water), so that polishing is interfered, besides not being economical.

Before a final polishing process of performing polishing using the polishing composition of this embodiment, a preliminary polishing process of performing polishing using another polishing composition may be provided. When the surface of the polishing target has processing damages, flaws generated in transportation, and the like, it takes a lot of time to mirror-finish the flaws by one polishing process, and therefore the process is uneconomical and there is a possibility that the smoothness of the surface of the polishing target may be impaired.

Then, by removing the flaws in the surface of the polishing target by the preliminary polishing process, the polishing time required for the final polishing process using the polishing composition of this embodiment can be shortened, so that the outstanding mirror surface can be efficiently obtained. As a preliminarily polishing composition for use in the preliminary polishing process, it is preferable to use one having stronger polishing force than that of the polishing composition of this embodiment. Specifically, it is preferable to use abrasives having higher hardness and a larger average primary particle diameter than those of abrasives for use in the polishing composition of this embodiment.

The type of the abrasives contained in the preliminarily polishing composition is not particularly limited and boron carbide, silicon carbide, aluminum oxide (alumina), zirconia, zircon, ceria, titania, and the like are mentioned, for example. The abrasives may be used singly or in combination of two or more kinds thereof. Among the abrasives, boron carbide and silicon carbide are particularly preferable as the abrasives contained in the preliminarily polishing composition. Boron carbide and silicon carbide may contain impurity elements, such as iron and carbon.

The average primary particle diameter of the abrasives contained in the preliminarily polishing composition may be 0.1 μm or more and preferably 0.3 μm or more. The average primary particle diameter of the abrasives contained in the preliminarily polishing composition maybe 20 μm or less and preferably 5 μm or less. With a reduction in the average primary particle diameter of the abrasives contained in the preliminarily polishing composition, a surface having few defects and low surface roughness is easily obtained. The average primary particle diameter of the abrasives contained in the preliminarily polishing composition can be measured with a laser diffraction/scattering type particle diameter distribution meter, for example. Examples of the device include “LA-950” manufactured by HORIBA, LTD.

The content of the abrasives in the preliminarily polishing composition may be 0.5 mass % or more and preferably 1 mass % or more. With an increase in the content of the abrasives, the polishing rate of the polishing target by the preliminarily polishing composition is improved. On the other hand, the content of the abrasives in the preliminarily polishing composition may be 40 mass % or less and preferably 30 mass % or less. With a reduction in the content of the abrasives, the production cost of the preliminarily polishing composition decreases.

A suitable pH of the preliminarily polishing composition varies depending on the type of the polishing target, the type of the abrasives, the average primary particle diameter of the abrasives, the production history of the abrasives, and the like similarly to the pH of the polishing composition of this embodiment. The pH of the preliminarily polishing composition is adjusted with acids, bases, or salts thereof similarly to the pH of the polishing composition of this embodiment.

The preliminarily polishing composition may contain various additives as desired similarly to the polishing composition of this embodiment and may contain a redispersion agent, for example. Examples of the redispersion agent include fine particles having an average primary particle diameter of 0.2 μm or less, a water-soluble polymer to be added as desired to the polishing composition of this embodiment, a water-soluble copolymer, or salts thereof.

The type of the fine particles having an average primary particle diameter of 0.2 μm or less is not particularly limited and alumina, zirconia, zircon, ceria, titania, silica, chromium oxide, iron oxide, silicon nitride, titanium nitride, titanium boride, tungsten boride, manganese oxide, and the like are mentioned, for example. The fine particles may be used singly or in combination of two or more kinds thereof. Moreover, fine particles containing a mixture of two or more kinds of the substances among the substances mentioned above may be used.

Among the above, metal oxides are preferable and alumina (for example, α-alumina, intermediate alumina, fumed alumina, alumina sol, or a mixture thereof), hydrated alumina (for example, boehmite), aluminum hydroxide, and silica (for example, colloidal silica, fumed silica, and sol-gel method silica) are more preferable in terms of ease of availability and low cost. The average primary particle diameter of the fine particles is preferably 0.005 μm or more and more preferably 0.01 μm or more from the viewpoint of ease of availability. The average primary particle diameter of the fine particles is preferably 0.5 μm or less, more preferably 0.2 μm or less, and still more preferably 0.1 μm or less. When the average primary particle diameter of the fine particles is within the ranges mentioned above, not only that the cost is reduced but that the sedimentation of the abrasives themselves is hard to occur, and the redispersibility of the abrasives of the preliminarily polishing composition further increases.

The polishing composition of this embodiment can be collected after used for the polishing of a polishing target to be reused for polishing of polishing target. As one example of a method for reusing the polishing composition, a method is mentioned which includes collecting the polishing composition discharged from the polishing device in a tank, and then circulating the same into the polishing device again to use the same for polishing. When the polishing composition is circularly used, the amount of the polishing composition discharged as a waste liquid can be reduced, and therefore an environmental load can be reduced. Moreover, the amount of the polishing composition to be used can be reduced, and therefore the production cost required for polishing of a polishing target can be reduced.

When the polishing composition of this embodiment is reused, the polishing composition may be reused after adding some or all of the abrasives, the metal protecting organic compound, the additives, and the like, which were consumed or lost due to the fact that the polishing composition was used for polishing, as a composition regulator. As the composition regulator, one in which the abrasives, the metal protecting organic compound, the additives, and the like are mixed at an arbitrary mixing ratio is usable. By additionally adding the composition regulator, the composition of the polishing composition is adjusted to a composition suitable for reuse, so that suitable polishing can be performed. The concentrations of the abrasives, the metal protecting organic compound, and the additives contained in the composition regulator are arbitrary and are not particularly limited and may be adjusted as appropriate according to the tank size and the polishing conditions.

Furthermore, the polishing composition of this embodiment may be a one-component type or may be a multi-component type, such as a two-component type in which some or all of the components of the polishing composition are mixed at an arbitrary ratio. In the polishing of a polishing target, the polishing target may be polished using an undiluted solution of the polishing composition of this embodiment as it is but may be polished using a dilution of the polishing composition obtained by diluting the undiluted solution with a diluted solution, such as water, 10 or more times.

### EXAMPLES

Hereinafter, the present invention is more specifically described with reference to Examples and Comparative Examples.

Abrasives (Average primary particle diameter of 35 nm) containing colloidal silica the surface of which is modified with a sulfonic acid group, various metal protecting organic compounds, water which is a liquid medium, and citric acid, polyacrylic acid, and hydrogen peroxide which are additives were mixed, and then the abrasives were dispersed in water, whereby polishing compositions of Examples 1 to 21 and Comparative Examples 1 to 70 were produced. In these polishing compositions, the content of the abrasives is 0.2 mass %, the content of the metal protecting organic compounds is 0.25 mass %, the content of the citric acid is 0.1 mass %, the content of the polyacrylic acid is 0.01 mass %, and the content of the hydrogen peroxide is 0.7 mass %, and the balance is water.

“POE” of “POE(5)-1-hexylheptylether” illustrated in Tables 1 to 4 means “polyoxyethylene” and “(5)” thereof means that the average repetition number of oxyethylene units of a polyoxyethylene group is 5. The same applies to “POE(20)-sorbitan monooleate” and “POE(60)-sorbitan tetraoleate”.

The depth of the oxidation reaction occurring when polishing compositions of Examples 1 to 21 and Comparative Examples 1 to 70 were brought into contact with a substrate having a metal film was measured. The depth of the oxidation reaction is a value obtained by adding the etching amount (depth) of the metal film and the thickness of an oxide film generated on the surface of the metal film. The depth of the oxidation reaction can be measured by measuring the reduction amount of the metal film and measuring the thickness of the oxide film by performing depth direction analysis (depth profile) by X-ray photoelectron spectroscopy (XPS) to the substrate, and then adding the reduction amount of the metal film and the thickness of the oxide film.

However, in Examples 1 to 21 and Comparative Examples 1 to 70, the depth of the oxidation reaction was not measured by the above-described method and was calculated based on the Faraday's law from a current value flowing in one minute by performing constant potential electrolysis of the substrate by electrochemical measurement. Specifically, the current-time curve when a voltage of +1.12−0.059×pH based on the potential of a reference electrode was applied to a working electrode using a potentiostat (Model 1280Z) manufactured by Solarton was measured, and then the amount of electricity was measured from the integrated value of the current-time curve. Herein, a blanket wafer on which each metal film was formed was used as the working electrode, a platinum substrate was used as a counter electrode, and a silver-silver chloride electrode was used as the reference electrode.

The measurement results of the depth of the oxidation reaction are illustrated in Tables 1 to 4. Then, a ratio to the depth of an oxidation reaction of Comparative Examples in which the metal type was the same and no metal protecting organic compounds were added ([Depth of oxidation reaction of Example]/[Depth of oxidation reaction of Comparative Example]) was calculated to be illustrated as the progress rate (The unit is %.) of the oxidation reaction in Tables 1 to 4. Furthermore, a case where the progress rate of the oxidation reaction was 50% or less was indicated as ⊙ because the addition effect of the metal protecting organic compound was very good, a case where the progress rate was more than 50% and less than 90% was indicated as ◯ because the addition effect of the metal protecting organic compound was good, and a case where the progress rate was 90% or more was indicated as x because the addition effect of the metal protecting organic compound was insufficient.

TABLE 1

| | Metal | | Metal protecting organic compound | | Depth | | |
|---|---|---|---|---|---|---|---|
| | | Standard | | pKa of | of oxidation | Progress rate of | |
| | | electrode potential | | interactive | reaction | oxidation | Addition |
| | Type | [V (vs. SHE)] | Type | functional group | [nm/min] | reaction [%] | effect |
| Comp. Ex. 1 | Al | Al/Al³⁺: −1.55 | None | — | 5.3 | — | — |
| Comp. Ex. 2 | Al | Al/Al³⁺: −1.55 | Benzotriazole | 12 | 5.4 | 102 | X |
| Comp. Ex. 3 | Al | Al/Al³⁺: −1.55 | Lauryl phosphate | 2 | 5.2 | 98 | X |
| Comp. Ex. 4 | Al | Al/Al³⁺: −1.55 | Triethanolamine lauryl sulfonate | −2 | 5.1 | 96 | X |
| Comp. Ex. 5 | Al | Al/Al³⁺: −1.55 | Sorbitan monolaurate | ND | 5.8 | 110 | X |
| Comp. Ex. 6 | Al | Al/Al³⁺: −1.55 | POE(5)-1-hexylheptylether | 15 | 5.9 | 112 | X |
| Comp. Ex. 7 | Al | Al/Al³⁺: −1.55 | POE(20)-sorbitan monooleate | 15 | 5.5 | 103 | X |
| Comp. Ex. 8 | Al | Al/Al³⁺: −1.55 | Dodecyl trimethyl ammonium chloride | 11 | 9.8 | 185 | X |
| Comp. Ex. 9 | Al | Al/Al³⁺: −1.55 | Polypropylene glycol (Mw: 500) | 15 | 5.6 | 106 | X |
| Comp. Ex. 10 | Fe | Fe/Fe²⁺: −0.44 | None | — | 57.3 | — | — |
| Comp. Ex. 11 | Fe | Fe/Fe²⁺: −0.44 | Benzotriazole | 12 | 58.0 | 101 | X |
| Ex. 1 | Fe | Fe/Fe²⁺: −0.44 | Sodium laurate | 5 | 49.4 | 86 | ◯ |
| Ex. 2 | Fe | Fe/Fe²⁺: −0.44 | Lauryl phosphate | 2 | 7.8 | 14 | ⊙ |
| Ex. 3 | Fe | Fe/Fe²⁺: −0.44 | Laureth-2 phosphate | 2 | 8.7 | 15 | ⊙ |
| Ex. 4 | Fe | Fe/Fe²⁺: −0.44 | Pareth-3 phosphate | 2 | 9.0 | 16 | ⊙ |
| Ex. 5 | Fe | Fe/Fe²⁺: −0.44 | Pareth-6 phosphate | 2 | 10.0 | 17 | ⊙ |
| Comp. Ex. 12 | Fe | Fe/Fe²⁺: −0.44 | Triethanolamine lauryl sulfonate | −2 | 54.2 | 95 | X |
| Comp. Ex. 13 | Fe | Fe/Fe²⁺: −0.44 | Sorbitan monolaurate | ND | 59.3 | 103 | X |
| Comp. Ex. 14 | Fe | Fe/Fe²⁺: −0.44 | POE(5)-1-hexylheptylether | 15 | 57.4 | 100 | X |
| Comp. Ex. 15 | Fe | Fe/Fe²⁺: −0.44 | POE(20)-sorbitan monooleate | 15 | 58.0 | 101 | X |
| Comp. Ex. 16 | Fe | Fe/Fe²⁺: −0.44 | Dodecyl trimethyl ammonium chloride | 11 | 142.5 | 248 | X |
| Comp. Ex. 17 | Fe | Fe/Fe²⁺: −0.44 | Polypropylene glycol (Mw: 500) | 15 | 57.2 | 100 | X |

TABLE 2

| | Metal | | Metal protecting organic compound | | Depth | Progress | |
|---|---|---|---|---|---|---|---|
| | | Standard | | pKa of | of oxidation | rate of | |
| | | electrode potential | | interactive | reaction | oxidation | Addition |
| | Type | [V (vs. SHE)] | Type | functional group | [nm/min] | reaction [%] | effect |
| Comp. Ex. 18 | Co | Co/Co²⁺: −0.28 | None | — | 28.1 | — | — |
| Comp. Ex. 19 | Co | Co/Co²⁺: −0.28 | Benzotriazole | 12 | 32.5 | 115 | X |
| Ex. 6 | Co | Co/Co²⁺: −0.28 | Sodium laurate | 5 | 21.9 | 78 | ◯ |
| Ex. 7 | Co | Co/Co²⁺: −0.28 | Lauryl phosphate | 2 | 3.2 | 11 | ⊙ |
| Comp. Ex. 20 | Co | Co/Co²⁺: −0.28 | Triethanolamine lauryl sulfonate | −2 | 28.9 | 103 | X |
| Comp. Ex. 21 | Co | Co/Co²⁺: −0.28 | Glycerol monostearate | 15 | 29.2 | 104 | X |
| Comp. Ex. 22 | Co | Co/Co²⁺: −0.28 | Polyoxyethylene-triisostearate | 15 | 26.2 | 93 | X |
| Comp. Ex. 23 | Co | Co/Co²⁺: −0.28 | Sorbitan monolaurate | ND | 33.6 | 119 | X |
| Comp. Ex. 24 | Co | Co/Co²⁺: −0.28 | POE(5)-1-hexylheptylether | 15 | 33.9 | 120 | X |
| Comp. Ex. 25 | Co | Co/Co²⁺: −0.28 | POE(20)-sorbitan monooleate | 15 | 26.6 | 95 | X |
| Comp. Ex. 26 | Co | Co/Co²⁺: −0.28 | POE(60)-sorbitan tetraoleate | 15 | 32.8 | 117 | X |
| Comp. Ex. 27 | Co | Co/Co²⁺: −0.28 | Dodecyl trimethyl ammonium chloride | 11 | 78.6 | 279 | X |
| Comp. Ex. 28 | Co | Co/Co²⁺: −0.28 | Betaine lauryldimethylaminoacetate | ND | 34.0 | 121 | X |
| Comp. Ex. 29 | Co | Co/Co²⁺: −0.28 | Sodium polystyrene sulfonate (Mw: 50000) | −2 | 75.3 | 268 | X |
| Comp. Ex. 30 | Co | Co/Co²⁺: −0.28 | Polyglycerol (Mw: 500) | 15 | 35.0 | 124 | X |
| Comp. Ex. 31 | Co | Co/Co²⁺: −0.28 | Polypropylene glycol (Mw: 500) | 15 | 35.9 | 128 | X |
| Ex. 8 | Co | Co/Co²⁺: −0.28 | Laureth-2 phosphate | 2 | 2.7 | 10 | ⊙ |
| Ex. 9 | Co | Co/Co²⁺: −0.28 | Pareth-3 phosphate | 2 | 4.1 | 14 | ⊙ |
| Ex. 10 | Co | Co/Co²⁺: −0.28 | Pareth-6 phosphate | 2 | 8.0 | 28 | ⊙ |
| Ex. 11 | Co | Co/Co²⁺: −0.28 | Pareth-6 phosphate | 2 | 10.3 | 37 | ⊙ |
| Comp. Ex. 32 | Co | Co/Co²⁺: −0.28 | Polyoxyethylene allyl phenyl ether | ND | 35.9 | 128 | X |
| | | | phosphate amine (Mw: 1600) | | | | |

TABLE 3

| | Metal | | Metal protecting organic compound | | Depth | Progress | |
|---|---|---|---|---|---|---|---|
| | | Standard | | pKa of | of oxidation | rate of | |
| | | electrode potential | | interactive | reaction | oxidation | |
| | Type | [V (vs. SHE)] | Type | functional group | [nm/min] | reaction [%] | Addition effect |
| Comp. Ex. 33 | Ni | Ni/Ni²⁺: −0.25 | None | — | 11.0 | — | — |
| Comp. Ex. 34 | Ni | Ni/Ni²⁺: −0.25 | Benzotriazole | 12 | 13.2 | 120 | X |
| Ex. 12 | Ni | Ni/Ni²⁺: −0.25 | Sodium laurate | 5 | 4.3 | 39 | ⊙ |
| Ex. 13 | Ni | Ni/Ni²⁺: −0.25 | Lauryl phosphate | 2 | 1.8 | 16 | ⊙ |
| Ex. 14 | Ni | Ni/Ni²⁺: −0.25 | Laureth-2 phosphate | 2 | 1.7 | 6 | ⊙ |
| Ex. 15 | Ni | Ni/Ni²⁺: −0.25 | Pareth-3 phosphate | 2 | 1.7 | 6 | ⊙ |
| Ex. 16 | Ni | Ni/Ni²⁺: −0.25 | Pareth-6 phosphate | 2 | 2.5 | 9 | ⊙ |
| Comp. Ex. 35 | Ni | Ni/Ni²⁺: −0.25 | Triethanolamine lauryl sulfonate | −2 | 9.7 | 88 | X |
| Comp. Ex. 36 | Ni | Ni/Ni²⁺: −0.25 | Sorbitan monolaurate | ND | 10.6 | 96 | X |
| Comp. Ex. 37 | Ni | Ni/Ni²⁺: −0.25 | POE(5)-1-hexylheptylether | 15 | 11.0 | 100 | X |
| Comp. Ex. 38 | Ni | Ni/Ni²⁺: −0.25 | POE(20)-sorbitan monooleate | 15 | 11.2 | 102 | X |
| Comp. Ex. 39 | Ni | Ni/Ni²⁺: −0.25 | Dodecyl trimethyl ammonium chloride | 11 | 28.1 | 255 | X |
| Comp. Ex. 40 | Ni | Ni/Ni²⁺: −0.25 | Polypropylene glycol (Mw: 500) | 15 | 10.1 | 92 | X |
| Comp. Ex. 41 | W | W/W⁴⁺: −0.12 | None | — | 14.3 | — | — |
| Comp. Ex. 42 | W | W/W⁴⁺: −0.12 | Benzotriazole | 12 | 12.9 | 90 | X |
| Ex. 17 | W | W/W⁴⁺: −0.12 | Sodium laurate | 5 | 10.7 | 75 | ◯ |
| Ex. 18 | W | W/W⁴⁺: −0.12 | Lauryl phosphate | 2 | 9.8 | 69 | ◯ |
| Ex. 19 | W | W/W⁴⁺: −0.12 | Laureth-2 phosphate | 2 | 9.4 | 65 | ◯ |
| Ex. 20 | W | W/W⁴⁺: −0.12 | Pareth-3 phosphate | 2 | 9.7 | 67 | ◯ |
| Ex. 21 | W | W/W⁴⁺: −0.12 | Pareth-6 phosphate | 2 | 10.2 | 71 | ◯ |
| Comp. Ex. 43 | W | W/W⁴⁺: −0.12 | Triethanolamine lauryl sulfonate | −2 | 14.1 | 98 | X |
| Comp. Ex. 44 | W | W/W⁴⁺: −0.12 | Sorbitan monolaurate | ND | 14.8 | 103 | X |
| Comp. Ex. 45 | W | W/W⁴⁺: −0.12 | POE(5)-1-hexylheptylether | 15 | 14.1 | 98 | X |
| Comp. Ex. 46 | W | W/W⁴⁺: −0.12 | POE(20)-sorbitan monooleate | 15 | 14.4 | 101 | X |
| Comp. Ex. 47 | W | W/W⁴⁺: −0.12 | Dodecyl trimethyl ammonium chloride | 11 | 25.2 | 176 | X |
| Comp. Ex. 48 | W | W/W⁴⁺: −0.12 | Polypropylene glycol (Mw: 500) | 15 | 14.2 | 99 | X |

TABLE 4

| | Metal | | Metal protecting organic compound | | Depth | Progress | |
|---|---|---|---|---|---|---|---|
| | | Standard | | pKa of | of oxidation | rate of | |
| | | electrode potential | | interactive | reaction | oxidation | |
| | Type | [V (vs. SHE)] | Type | functional group | [nm/min] | reaction [%] | Addition effect |
| Comp. Ex. 49 | Cu | Cu/Cu²⁺: 0:34 | None | — | 28.1 | — | — |
| Comp. Ex. 50 | Cu | Cu/Cu²⁺: 0:34 | Benzotriazole | 12 | 11.7 | 42 | ⊙ |
| Comp. Ex. 51 | Cu | Cu/Cu²⁺: 0:34 | Sodium laurate | 5 | 26.1 | 93 | X |
| Comp. Ex. 52 | Cu | Cu/Cu²⁺: 0:34 | Lauryl phosphate | 2 | 44.5 | 158 | X |
| Comp. Ex. 53 | Cu | Cu/Cu²⁺: 0:34 | Laureth-2 phosphate | 2 | 43.6 | 155 | X |
| Comp. Ex. 54 | Cu | Cu/Cu²⁺: 0:34 | Pareth-3 phosphate | 2 | 44.1 | 157 | X |
| Comp. Ex. 55 | Cu | Cu/Cu²⁺: 0:34 | Pareth-6 phosphate | 2 | 43.1 | 153 | X |
| Comp. Ex. 56 | Cu | Cu/Cu²⁺: 0:34 | Sorbitan monolaurate | ND | 27.7 | 99 | X |
| Comp. Ex. 57 | Cu | Cu/Cu²⁺: 0:34 | POE(5)-1-hexylheptylether | 15 | 27.1 | 96 | X |
| Comp. Ex. 58 | Cu | Cu/Cu²⁺: 0:34 | POE(20)-sorbitan monooleate | 15 | 27.8 | 99 | X |
| Comp. Ex. 59 | Cu | Cu/Cu²⁺: 0:34 | Dodecyl trimethyl ammonium chloride | 11 | 29.8 | 106 | X |
| Comp. Ex. 60 | Cu | Cu/Cu²⁺: 0:34 | Polypropylene glycol (Mw: 500) | 15 | 28.0 | 100 | X |
| Comp. Ex. 61 | Ru | Ru/Ru²⁺: 0:46 | None | — | 27.3 | — | — |
| Comp. Ex. 62 | Ru | Ru/Ru²⁺: 0:46 | Benzotriazole | 12 | 27.0 | 99 | X |
| Comp. Ex. 63 | Ru | Ru/Ru²⁺: 0:46 | Sodium laurate | 5 | 26.7 | 98 | X |
| Comp. Ex. 64 | Ru | Ru/Ru²⁺: 0:46 | Lauryl phosphate | 2 | 26.1 | 96 | X |
| Comp. Ex. 65 | Ru | Ru/Ru²⁺: 0:46 | Triethanolamine lauryl sulfonate | −2 | 27.4 | 100 | X |
| Comp. Ex. 66 | Ru | Ru/Ru²⁺: 0:46 | Sorbitan monolaurate | ND | 27.2 | 100 | X |
| Comp. Ex. 67 | Ru | Ru/Ru²⁺: 0:46 | POE(5)-1-hexylheptylether | 15 | 27.3 | 100 | X |
| Comp. Ex. 68 | Ru | Ru/Ru²⁺: 0:46 | POE(20)-sorbitan monooleate | 15 | 27.1 | 99 | X |
| Comp. Ex. 69 | Ru | Ru/Ru²⁺: 0:46 | Dodecyl trimethyl ammonium chloride | 11 | 26.5 | 97 | X |
| Comp. Ex. 70 | Ru | Ru/Ru²⁺: 0:46 | Polypropylene glycol (Mw: 500) | 15 | 26.6 | 97 | X |

Furthermore, Examples 7 to 11 and Comparative Example 18 were measured for the corrosion potential. When the corrosion potential is higher than that of Comparative Example containing no metal protecting organic compounds, it can be judged that corrosion is improved by the addition of the metal protecting organic compound. The corrosion potential can be measured using a potentiostat (Model 1280Z) manufactured by Solarton. The corrosion potential was determined from the Tafel curve obtained by scanning a voltage at a scanning rate of 5 mV/sec within the range of immersion potential of ±1.0 V. The results are illustrated in Table 5.

TABLE 5

| | Metal | | Metal protecting organic compound | | |
|---|---|---|---|---|---|
| | | Standard electrode | | Average | Corrosion |
| | | potential | | addition number | potential |
| | Type | [V (vs. SHE)] | Type | of moles | [V (vs. Ag/AgCl] |
| Comp. | Co | Co/Co²⁺: −0.28 | None | — | 0.04 |
| Ex. 18 | | | | | |
| Ex. 7 | Co | Co/Co²⁺: −0.28 | Lauryl phosphate | 0 | 0.10 |
| Ex. 8 | Co | Co/Co²⁺: −0.28 | Laureth-2 phosphate | 2 | 0.43 |
| Ex. 9 | Co | Co/Co²⁺: −0.28 | Pareth-3 phosphate | 3 | 0.39 |
| Ex. 10 | Co | Co/Co²⁺: −0.28 | Pareth-6 phosphate | 6 | 0.06 |
| Ex. 11 | Co | Co/Co²⁺: −0.28 | Pareth-9 phosphate | 9 | −0.02 |

As is understood from Tables 1 to 4, the progress rate of the oxidation reaction of Example 1 to 21 was less than 90% and the addition effect of the metal protecting organic compound was very good or good. On the other hand, the progress rate of the oxidation reaction of Comparative Examples (excluding Comparative Examples 1, 10, 18, 33, 41, 49, 50, and 61) was 90% or more and the addition effect of the metal protecting organic compound was insufficient.

1. A polishing composition for polishing a polishing target containing a transition metal having a standard electrode potential of −0.45 V or more and 0.33 V or less, the polishing composition comprising:
abrasives; and
a metal protecting organic compound,
wherein the metal protecting organic compound has an interactive functional group which is a functional group interacting with the polishing target and an inhibiting functional group which is a functional group inhibiting approach of the abrasives toward the polishing target.

2. The polishing composition according to claim 1, wherein an acid dissociation constant pKa of the interactive functional group is 1 or more and 6 or less.

3. The polishing composition according to claim 1 or 2, wherein the interactive functional group is at least one of a phosphoric acid group (H2PO4—) and a carboxy group (—COOH).

4. The polishing composition according to claim 1, wherein the inhibiting functional group is an alkyl group having 1 or more and 20 or less carbon atoms or a polyoxyethylene group represented by a chemical formula —(OCH2CH2)n, wherein n in the chemical formula is an integer of 1 or more and 10 or less.

5. The polishing composition according to claim 1, wherein the interaction is at least one chemical bond of an ionic bond, a covalent bond, and a hydrogen bond.

6. A polishing method comprising:
polishing a polishing target using the polishing composition according to claim 1.

7. The polishing composition according to claim 2, wherein the interactive functional group is at least one of a phosphoric acid group (H2PO4—) and a carboxy group (—COOH).

8. The polishing composition according to claim 2, wherein the inhibiting functional group is an alkyl group having 1 or more and 20 or less carbon atoms or a polyoxyethylene group represented by a chemical formula —(OCH2CH2)n, wherein n in the chemical formula is an integer of 1 or more and 10 or less.

9. The polishing composition according to claim 3, wherein the inhibiting functional group is an alkyl group having 1 or more and 20 or less carbon atoms or a polyoxyethylene group represented by a chemical formula —(OCH2CH2)n, wherein n in the chemical formula is an integer of 1 or more and 10 or less.

10. The polishing composition according to claim 2, wherein the interaction is at least one chemical bond of an ionic bond, a covalent bond, and a hydrogen bond.

11. The polishing composition according to claim 3, wherein the interaction is at least one chemical bond of an ionic bond, a covalent bond, and a hydrogen bond.

12. The polishing composition according to claim 4, wherein the interaction is at least one chemical bond of an ionic bond, a covalent bond, and a hydrogen bond.

13. A polishing method comprising:
polishing a polishing target using the polishing composition according to claim 2.

14. A polishing method comprising:
polishing a polishing target using the polishing composition according to claim 3.

15. A polishing method comprising:
polishing a polishing target using the polishing composition according to claim 4.

16. A polishing method comprising:
polishing a polishing target using the polishing composition according to claim 5.
